(19) United States
(12) Patent Application Publication
(10) Pub. No.: US 2026/0063697 A1
(43) Pub. Date: Mar. 5, 2026

(54) APPARATUS FOR MEASURING STATIC ELECTRICITY

(71) Applicant: Samsung Electronics Co., LTD., Suwon-si (KR)

(72) Inventors: Sang Yoon HAN, Suwon-si (KR); Gyou II Jeong, Suwon-si (KR); Dae Sung Jung, Suwon-si (KR); Myeong Ock Ko, Suwon-si (KR); Seong Beom Lee, Suwon-si (KR)

(73) Assignee: Samsung Electronics Co., LTD., Suwon-si (KR)

(21) Appl. No.: 19/098,303

(22) Filed: Apr. 2, 2025

(30) Foreign Application Priority Data
Aug. 28, 2024 (KR) 10-2024-0116202
Nov. 14, 2024 (KR) 10-2024-0161708

(51) Int. Cl. G01R 29/12

(52) U.S. Cl. CPC G01R 29/12

(57) ABSTRACT

An apparatus for measuring static electricity according to some embodiments is provided. The apparatus for measuring static electricity includes a first probe spaced apart from a first surface of a measurement object by a first distance; and a second probe spaced apart from a second surface, opposing the first surface in a thickness direction of the measurement object, by a second distance, wherein the first probe includes a first casing, and a first electrostatic measurement structure provided in the first casing and configured to measure static electricity in a first measurement region included in the first surface, wherein the first distance and the second distance are smaller than a thickness of the measurement object.

### CROSS-REFERENCE TO RELATED APPLICATIONS

This application claims priority from Korean Patent Application Nos. 10-2024-0116202, filed on Aug. 28, 2024, and 10-2024-0161708, filed on Nov. 14, 2024, in the Korean Intellectual Property Office and all the benefits accruing therefrom under 35 U.S.C. 119, the disclosures of which are herein incorporated by reference in their entireties.

### BACKGROUND

### 1. Field

One or more example embodiments of the disclosure relate to an apparatus for measuring static electricity.

### 2. Description of the Related Art

In a substrate which is manufactured into a semiconductor or a display through various substrate processing processes such as a deposition, an exposure, an etching, and cleaning, static electricity may be generated on a surface of the substrate during various substrate processing processes. For example, in a process of spraying a processing liquid onto the surface of the substrate, the static electricity may be generated on the surface of the substrate due to a friction between the processing liquid and the substrate surface.

If the static electricity generated on the surface of the substrate is not discharged and remains on the surface of the substrate, particles and the like may flow into a substrate processing equipment and the particles may adhere to the surface of the substrate to contaminate the substrate. In addition, when the substrate is spaced apart from an electrostatic chuck using a transfer arm that transfers the substrate, the substrate may not be separated well from the electrostatic chuck due to residual static electricity on the substrate surface, which may damage the substrate, the transfer arm, and the like, and may require the substrate processing equipment to be stopped. Furthermore, the residual static electricity on the substrate surface may cause defective alignment and focusing of the substrate, and arcing may be generated to damage the substrate and the substrate processing equipment.

The above-mentioned problems caused by the residual static electricity on the substrate surface may be prevented by measuring the static electricity on the substrate surface in a non-contact manner so as not to damage the substrate surface.

There is an electrostatic fieldmeter as a related art non-contact apparatus for measuring static electricity. The electrostatic fieldmeter is a capacitor type apparatus that measures the static electricity on a surface of a measurement object in a non-contact manner at a distance of about 1 inch (2.54 cm) from the measurement object. Such an electrostatic fieldmeter is affected by an external electric field, and when measuring the static electricity on one side of the measurement object, an electrostatic field caused by static electricity on an opposite side to the one side of the measurement object overlaps an electrostatic field caused by the static electricity on the one side of the measurement object. In addition, the electrostatic fieldmeter may not simultaneously measure the static electricity on one side of the measurement object and the static electricity on the opposite side. In addition, the electrostatic fieldmeter has a spatial resolution of about 10 cm. Therefore, the electrostatic fieldmeter is not suitable for measuring the electrostatic distribution on the surface of a substrate having a diameter of about 300 mm.

A Kelvin probe force microscopy (KPFM) is a non-contact apparatus for measuring static electricity other than the electrostatic fieldmeter. The Kelvin probe force microscope is configured to measure static electricity between a tip of an atomic force microscope (AFM) and the surface of a measurement object, and measure static electricity on the surface of the measurement object at an ultra-close distance of about 50 nm. The Kelvin probe force microscope measures a relative potential, and may contaminate the surface of the measurement object by measuring at an ultra-close distance. Also, an organic material may adhere to the Kelvin probe force microscope, and if there is an organic thin film on the Kelvin probe force microscope, the Kelvin probe force microscope may not be capable of measuring the static electricity. In addition, a tip of the Kelvin probe force microscope has a limited durability, and when measuring the static electricity on one side of the measurement object, a ground plate needs to be installed on the opposite side, and it is not possible to simultaneously measure the static electricity on one side of the measurement object and the static electricity on the opposite side. Furthermore, the Kelvin probe force microscope is expensive to measure the static electricity. Therefore, the Kelvin probe force microscope is not suitable for measuring the electrostatic distribution on the surface of a substrate having a diameter of about 300 mm.

### SUMMARY

Aspects of the disclosure provide an apparatus for measuring static electricity that may accurately measure static electricity on a surface of a measurement object in a non-contact manner, while preventing surface contamination and influence from other electric fields.

The objects of the disclosure are not limited to those mentioned above and additional objects of the disclosure, which are not mentioned herein, will be clearly understood by those skilled in the art from the following description of the disclosure.

According to an aspect of an example embodiment of the disclosure, an apparatus for measuring a static electricity is provided. The apparatus for measuring a static electricity includes: a first probe spaced apart from a first surface of a measurement object by a first distance; and a second probe spaced apart from a second surface by a second distance, the second surface opposing the first surface in a thickness direction of the measurement object, wherein the first probe includes: a first casing; and a first electrostatic measurement structure provided in the first casing, and configured to measure a static electricity in a first measurement region included in the first surface, wherein the first distance and the second distance are smaller than a thickness of the measurement object, wherein the first casing is earthed to a ground, and wherein the first electrostatic measurement structure is earthed to the ground separately from the first casing.

According to an aspect of an example embodiment of the disclosure, an apparatus for measuring a static electricity is provided. The apparatus for measuring a static electricity includes: a first probe spaced apart from a first surface of a measurement object by a first distance; and a second probe spaced apart from a second surface by a second distance, the second surface opposing the first surface in a thickness direction of the measurement object, wherein the first probe includes: a first casing; and a first electrostatic measurement structure provided in the first casing to measure a static electricity of a first measurement region included in the first surface, wherein the first distance and the second distance are smaller than a thickness of the measurement object, wherein the first casing is earthed to a ground, wherein the first electrostatic measurement structure is earthed to the ground separately from the first casing, wherein the first casing includes a first measuring hole which faces the first surface and corresponds to the first measurement region, wherein the first casing includes a metal or an electrostatic dissipative material, wherein the second probe is earthed to the ground and includes a metal or an electrostatic dissipative material, wherein the second probe includes an electrostatic field separation face that faces the second surface, and wherein the electrostatic field separation face has a size equal to or larger than a size of the first measuring hole.

According to an aspect of an example embodiment of the disclosure, an apparatus for measuring a static electricity is provided. The apparatus for measuring a static electricity includes: a first probe spaced apart from a first surface of a measurement object by a first distance; and a second probe spaced apart from a second surface by a second distance, the second surface opposing the first surface in a thickness direction of the measurement object, wherein the first probe includes: a first casing; and a first electrostatic measurement structure provided in the first casing and configured to measure a static electricity of a first measurement region included in the first surface, wherein the second probe includes: a second casing; and a second electrostatic measurement structure provided in the second casing and configured to measure a static electricity of a second measurement region included in the second surface, wherein the first distance and the second distance are smaller than a thickness of the measurement object, wherein each of the first casing and the second casing are earthed to a ground, wherein the first electrostatic measurement structure is earthed to the ground separately from the first casing, wherein the second electrostatic measurement structure is earthed to the ground separately from the second casing, wherein the first casing includes a first measuring hole which faces the first surface and corresponds to the first measurement region, wherein the second casing includes a second measuring hole that faces the second surface to corresponds to the second measurement region, and wherein each of the first casing and the second casing includes a metal or electrostatic dissipative material.

Specific details of other embodiments are included in the detailed description and drawings.

### BRIEF DESCRIPTION OF THE DRAWINGS

The above and other aspects and features of the disclosure will become more apparent by describing in detail example embodiments thereof with reference to the attached drawings.

FIGS. 1 and 2 are diagrams showing an apparatus for measuring static electricity according to some embodiments of the disclosure.

FIG. 3 is a diagram showing static electricity measurement of a first measurement region using a first probe of the apparatus for measuring static electricity of FIG. 1.

FIG. 4 is a diagram showing a first casing head and a first casing body of a first probe of the apparatus for measuring static electricity of FIG. 1.

FIG. 5 shows a first probe of the apparatus for measuring static electricity of FIG. 1 having first measuring holes of different sizes from each other.

FIG. 6 is a diagram showing an apparatus for measuring static electricity according to some embodiments of the disclosure.

FIG. 7 is a diagram showing that a first measurement face of a first probe of the apparatus for measuring static electricity of FIG. 6 have different radii of curvature from each other.

FIG. 8 is a diagram showing an apparatus for measuring static electricity according to some embodiments of the disclosure.

FIG. 9 is a diagram showing an apparatus for measuring static electricity according to some embodiments of the disclosure.

FIG. 10 is a diagram showing an example of measurement of electrostatic distribution by an apparatus for measuring static electricity according to some embodiments of the disclosure.

FIG. 11 is a diagram showing an apparatus for measuring static electricity according to some embodiments of the disclosure.

FIG. 12 is a diagram showing an apparatus for measuring static electricity according to some embodiments of the disclosure.

FIG. 13 is a diagram showing an example of measuring, by the apparatus for measuring static electricity of FIG. 12, an electrostatic distribution of a first surface or the first surface and a second surface of a measurement object.

FIG. 14 is a diagram showing another example of measurement of electrostatic distribution by the apparatus for measuring static electricity of FIG. 12.

FIG. 15 is a diagram showing an apparatus for measuring static electricity according to some embodiments of the disclosure.

FIG. 16 is a diagram showing various shapes of a first probe holder and a second probe holder of the apparatus for measuring static electricity of FIG. 15.

FIG. 17 is a diagram showing an example of measurement of electrostatic distribution by the apparatus for measuring static electricity of FIG. 15.

FIG. 18 is a diagram showing an apparatus for measuring static electricity according to some embodiments of the disclosure.

FIG. 19 is a graph showing static electricity of different measurement regions measured simultaneously over time by the apparatus for measuring static electricity according to some embodiments of the disclosure.

### DETAILED DESCRIPTION

Although terms such as first, second, upper, and lower are used herein to describe various elements or components, it should be understood that these elements or components are not limited by the terms. Rather, the terms are merely used herein to distinguish one element or component from another element or component. Therefore, it should be understood that a first element or component as mentioned below may also be a second element or component within the technical spirit of the disclosure. Further, it should be understood that a lower element or component as mentioned below may also be an upper element or component within the technical spirit of the disclosure.

Hereinafter, embodiments of the disclosure are described in detail with reference to the attached drawings. The same reference numerals may be used for the same components in the drawings, and duplicate descriptions thereof may be omitted.

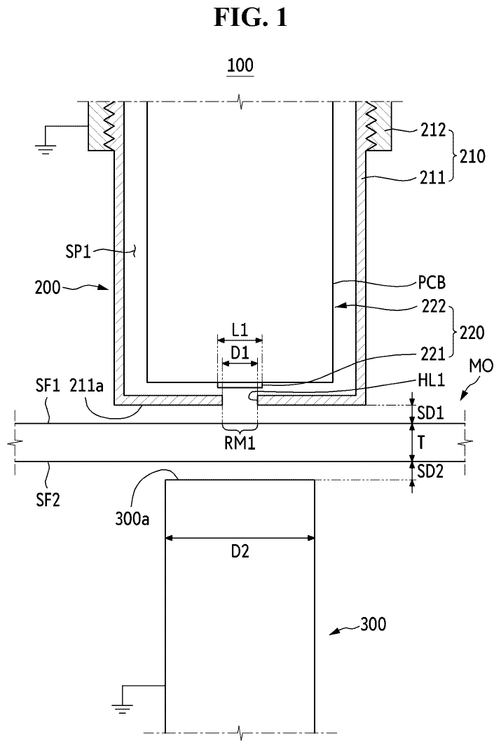

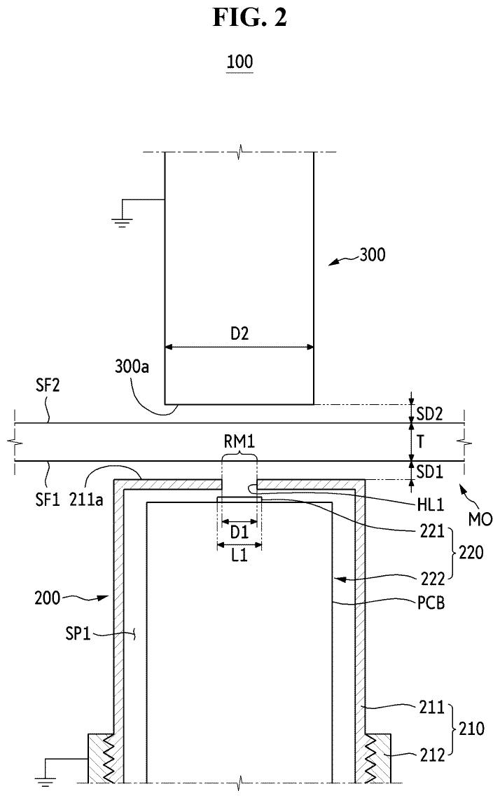

FIG. 1 is a diagram that shows an apparatus for measuring static electricity according to some embodiments of the disclosure, and shows that static electricity of a first measurement region of a first surface of a measurement object is measured, when the first surface is an upper side (or upper surface) of the measurement object. FIG. 2 is an apparatus for measuring static electricity of FIG. 1, and shows that the static electricity of the first measurement region of the first surface of the measurement object is measured, when the first surface is a lower side (or lower surface) of the measurement object.

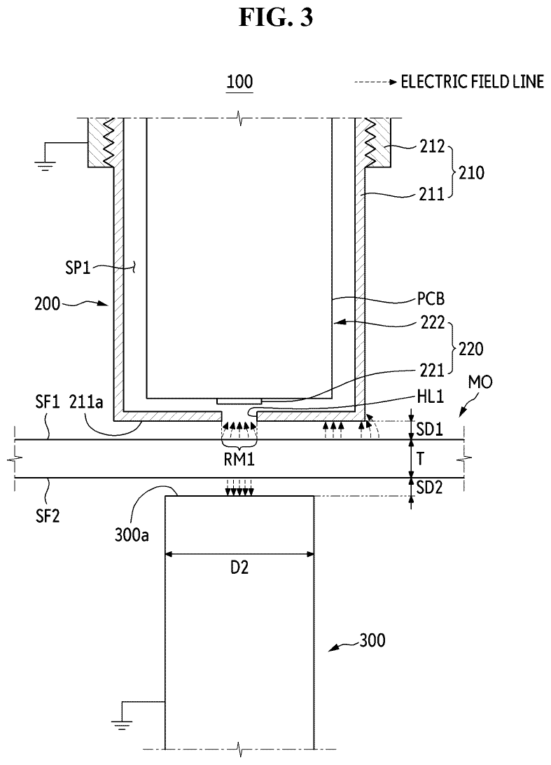

FIG. 3 is a diagram showing that an electric field generated in a region other than the first measurement region does not affect the static electricity measurement of the first measurement region of the measurement object using a first probe of the apparatus for measuring static electricity of FIG. 1.

Referring to FIGS. 1 to 3, an apparatus 100 for measuring static electricity (or static electricity measurement apparatus) may measure an electrostatic distribution of a first surface SF1 of a measurement object MO. The static electricity measurement apparatus 100 may accurately measure the electrostatic distribution on the first surface SF1 of the measurement object MO in a non-contact manner, while preventing contamination of the first surface SF1 and influence from other electric fields generated outside of a measurement region of the measurement object MO. For example, the measurement object MO may be a substrate such as a wafer or a glass substrate. The static electricity measurement apparatus 100 may also be included in a substrate processing equipment (not shown) that performs processing the substrate, such as deposition, exposure, etching, or cleaning. The static electricity measurement apparatus 100 may measure the electrostatic distribution on the first surface SF1 of the substrate. The static electricity measurement apparatus 100 may accurately measure the electrostatic distribution on the first surface SF1 of the substrate in a non-contact manner, while preventing the contamination of the first surface SF1 and influence from other electric fields. However, the measurement object MO is not limited thereto. The static electricity measurement apparatus 100 includes a first probe 200, a second probe 300, and the like.

The first probe 200 may measure the static electricity of a first measurement region RM1 included in the first surface SF1 of the measurement object MO in a non-contact manner. For example, the first probe 200 may measure potential or the like of the static electricity of the first measurement region RM1 included in the first surface SF1 of the measurement object MO in a non-contact manner. The first probe 200 may measure the static electricity of the first measurement region RM1 of the first surface SF1 of the measurement object MO in a non-contact manner, and the first probe 200 may not come into contact with the first surface SF1 of the measurement object MO. In addition, contamination of the first surface SF1 caused by the first probe 200 may be prevented. Further, damage to the first surface SF1, the measurement object MO, and the like caused by the first probe 200 may be prevented.

The first surface SF1 of the measurement object MO may be the upper side (or upper surface) of the measurement object MO as shown in FIG. 1, or may be the lower side (or lower surface) of the measurement object MO as shown in FIG. 2.

The first probe 200 may be spaced apart from the first surface SF1 of the measurement object MO by a first distance SD1. For example, the first probe 200 may be raised and lowered by a first probe elevator (not shown), and the first probe 200 may be raised and lowered by the first probe elevator, to be spaced apart from the first surface SF1 by the first distance SD1. Also, the first probe 200 may be moved in a horizontal direction by a first probe mover (not shown). The first probe 200 may measure the static electricity of a plurality of first measurement regions RM1 spaced apart from each other on the first surface SF1 of the measurement object MO, while moving in the horizontal direction by the first probe mover, thereby measuring the electrostatic distribution on the first surface SF1. For example, the first probe 200 may perform a raster scan or a snake scan on the first surface SF1 of the measurement object MO by the first probe mover. In addition, the first probe 200 may sequentially measure the static electricity of the plurality of first measurement regions RM1 spaced apart from one another on the first surface SF1, and measure the electrostatic distribution on the first surface SF1 of the measurement object MO. Problems that may occur due to static electricity may be prevented by utilizing the electrostatic distribution on the first surface SF1 of the measurement object MO measured in this manner.

The first distance SD1 may be smaller than a thickness T of the measurement object MO. When the first distance SD1 is smaller than the thickness T of the measurement object MO, the first probe 200 may measure the static electricity of the first measurement region RM1, in a state of being close to the first measurement region RM1 on the first surface SF1 of the measurement object MO. The first distance SD1 may be a distance that may prevent the contamination and damage to the first surface SF1 of the measurement object MO caused by the first probe 200, while being smaller than the thickness T of the measurement object MO. Further, the first distance SD1 may be a distance at which an organic material on the first surface SF1 of the measurement object MO may not adhere to the first probe 20, while being smaller than the thickness T of the measurement object MO. The first distance SD1 may be ⅔ or less of the thickness T of the measurement object MO. If the first distance SD1 is greater than ⅔ of the thickness T of the measurement object MO, an electrostatic field caused by the static electricity in the first measurement region RM1 of the measurement object MO may not reach the first probe 200 sufficiently. In addition, the measurement of the static electricity in the first measurement region RM1 of the measurement object MO by the first probe 200 may not be accurate. For example, if the measurement object MO is a substrate having a thickness T of about 775 μm, the first distance SD1 may be 80 μm to 100 μm. The first probe 200 includes a first casing 210, a first electrostatic measuring structure 220, and the like.

The first casing 210 may provide an external shape of the first probe 200, support the first electrostatic measurement structure 220, and may protect the first electrostatic measurement structure 220 from an outside. The first casing 210 may be earthed to ground. Because the first casing 210 may be earthed to ground, the first electrostatic measurement structure 220 may not be affected by electric fields other than the electrostatic field caused by the static electricity of the first measurement region RM1 of the first surface SF1 of the measurement object MO. That is to say, as shown in FIG. 3, electric fields other than the electrostatic field caused by the static electricity of the first measurement region RM1 of the measurement object MO may face toward a region of the first casing 210 other than a first measuring hole HL1, without facing toward the first measuring hole HL1 that corresponds to the first measurement region RM1. In addition, the measurement of the static electricity of the first measurement region RM1 of the measurement object MO by the first electrostatic measurement structure 220 may be accurate. The first casing 210 may include a metal or an electrostatic dissipative material. The electrostatic dissipative material may be a material having a surface resistance of 105 ohms/sq to 1011 ohms/sq, and has insulating properties, but may conduct static electricity on the surface. The electrostatic dissipative material may include an engineering plastic or a fluoropolymer. For example, the electrostatic dissipative material may include electrostatic discharge polyetheretherketone (ESD PEEK), carbon nanotube polymer, conductive and electrostatic discharge (ESD) plastic, polytetrafluoroethylene (PTFE) with a trademark Teflon, and the like. The first casing 210 may include the first measuring hole HL1 and a space SP1 in which the first measurement structure placement is disposed.

The first measuring hole HL1 may correspond to a position of the first measurement region RM1 on the first surface SF1 of the measurement object MO. The first measuring hole HL1 may face the first surface SF1 to correspond to the first measurement region RM1. In other words, a portion of the first surface SF1 which the first measuring hole HL1 faces may be the first measurement region RM1. The first measuring hole HL1 may be spaced apart from the first surface SF1 by the first distance SD1, and may face the first surface SF1 to form the first measurement region RM1. A first electrostatic sensor 221 of the first electrostatic measurement structure 220 may sense the electrostatic field caused by the static electricity in the first measurement region RM1 through the first measuring hole HL1, and may measure the static electricity of the first measurement region RM1. As described above, since the first casing 210 may be earthed to ground, the electric field other than the first measurement region RM1 of the measurement object MO may face the first casing 210 other than the first measuring hole HL1, without facing the first measuring hole HL1. Accordingly, the first electrostatic sensor 221 may not sense the electric field other than the first measurement region RM1 of the measurement object MO.

A size (or length) of the first measuring hole HL1 may be large enough that the first electrostatic sensor 221 of the first electrostatic measurement structure 220 may sense the static electricity of the first measurement region RM1 of the measurement object MO. The first measuring hole HL1 may have a size of 1/10 or more of the thickness T of the measurement object MO. When the size of the first measuring hole HL1 is smaller than 1/10 of the thickness T of the measurement object MO, the first electrostatic sensor 221 may not sense or may not sufficiently sense the static electricity of the first measurement region RM1. For example, if the first measuring hole HL1 has a circular shape, a diameter D1 of the first measuring hole HL1 may be 1/10 or more of the thickness T of the measurement object MO.

As it will be described below, the size of the first measuring hole HL1 may be changed. As the size of the first measuring hole HL1 changes, the size of the first measurement region RM1 of the measurement object MO may also be changed. When the size of the first measuring hole HL1 increases, the size of the first measurement region RM1 also increases, and a magnitude of potential of the static electricity measured by the first electrostatic measurement structure 220 may increase. However, a spatial resolution of the first probe 200 may increase. Also, when the size of the first measuring hole HL1 decreases, the size of the first measurement region RM1 decreases, and the magnitude of potential of the static electricity measured by the first electrostatic measurement structure 220 may decrease. However, the spatial resolution of the first probe 200 may decrease. Taking this into consideration, the size of the first measuring hole HL1 may be selected in accordance with desired measurement conditions. For example, if the measurement object MO is a substrate having a diameter of about 300 mm, the size of the first measuring hole HL1 may be selected such that the magnitude of potential of the static electricity of the first measurement region RM1 measured by the first electrostatic measurement structure 220 is also sufficiently large, and the spatial resolution is 0.5 mm to 3 mm. On the other hand, even if the spatial resolution is greater than a predetermined condition or a number of the first measurement regions RM1 is smaller than a predetermined number, an electrostatic distribution on the first surface SF1 of the measurement object MO may be measured by utilizing a super-resolution technique using a Gaussian distribution. The first measuring hole HL1 may be formed in a first casing head 211 of the first casing 210, which will be described below.

The first electrostatic measurement structure 220 may be disposed in the space SP1. The space SP1 may communicate with the first measuring hole HL1. In addition, the first electrostatic sensor 221 of the first electrostatic measurement structure 220 may sense the static electricity of the first measurement region RM1 on the first surface SF1 of the measurement object MO through the first measuring hole HL1. The space SP1 may be formed in the first casing head 211 and a first casing body 212 of the first casing 210.

The first casing 210 may include the first casing head 211, the first casing body 212, and the like.

The first casing head 211 may be spaced apart from the first surface SF1 of the measurement object MO by the first distance SD1. The first measuring hole HL1 may be formed in the first casing head 211. A part of the first electrostatic measurement structure 220, such as the first electrostatic sensor 221 of the first electrostatic measurement structure 220, may be disposed in the first casing head 211.

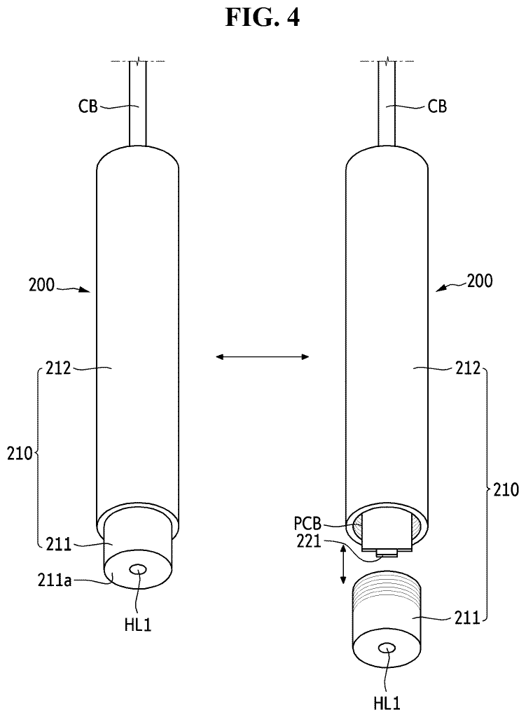

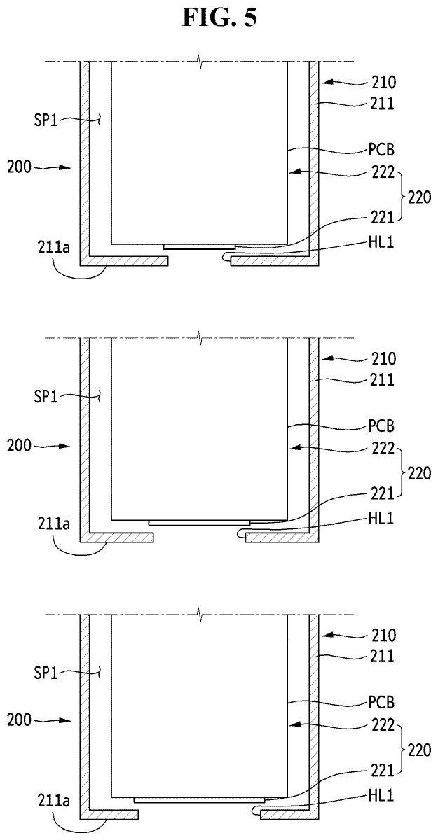

FIG. 4 is a diagram showing that the first casing head and the first casing body of the first probe of the apparatus for measuring static electricity of FIG. 1 are separated and connected, and FIG. 5 shows that the first probe of the apparatus for measuring static electricity of FIG. 1 has first measuring holes of different sizes from each other.

Referring to FIGS. 4 and 5, the first casing head 211 may be detachably connected to the first casing body 212. For example, a male screw thread may be formed on the first casing head 211 and a female screw thread may be formed on the first casing body 212, and thus, the first casing head 211 may be detachably connected to the first casing body 212. However, the configuration in which the first casing head 211 is detachably connected to the first casing body 212 is not limited thereto.

A plurality of first casing heads 211 may be provided, and the first measuring holes HL1 of the plurality of first casing heads 211 may have different sizes from each other. In addition, by connecting one of the first casing heads 211 having different sizes of the first measuring holes HL1 to the first casing body 212, the first measuring hole HL1 of the first casing 210 may have a size among various sizes. In other words, the size of the first measuring hole HL1 of the first casing 210 may be changed. In addition, the size of the first measuring hole HL1 may be changed in accordance with the desired measurement conditions. The first casing head 211 may have a cylindrical shape. However, the shape of the first casing head 211 is not limited thereto.

The first casing head 211 may include a first sensing surface 211a. The first sensing surface 211a may face the first surface SF1 of the measurement object MO, and the first measuring hole HL1 may be formed thereon. For example, the first sensing surface 211a may be a plane.

The first casing body 212 may support the first casing head 211 by being detachably connected to the first casing head 211. Other parts of the first electrostatic measurement structure 220, such as a first measuring circuit 222 to be described below, may be disposed in the first casing body 212. The first casing body 212 may have an integrated rod shape. However, the shape of the first casing body 212 is not limited thereto, and may have various shapes such as, for example, an “L” or “U”-shaped rod shape.

Referring again to FIGS. 1 to 3, the first electrostatic measurement structure 220 may measure static electricity in the first measuring region RM1 of the first surface SF1 of the measurement object MO. The first electrostatic measurement structure 220 may be disposed in the first casing 210. The first electrostatic measurement structure 220 may be disposed in the space SP1 of the first casing 210. The first electrostatic measurement structure 220 may be earthed to ground separately from the first casing 210. Since the first electrostatic measurement structure 220 may be earthed to ground separately from the first casing 210, the first electrostatic measurement structure 220 may measure static electricity in the first measurement region RM1 of the measurement object MO without being affected by the first casing 210. The first electrostatic measurement structure 220 may include the first electrostatic sensor 221 and the first measuring circuit 222.

The first electrostatic sensor 221 may sense the static electricity in the first measurement region RM1 of the first surface SF1 of the measurement object MO through the first measuring hole HL1. The static electricity in the first measurement region RM1 sensed by the first electrostatic sensor 221 may be measured by the first measuring circuit 222. The first electrostatic sensor 221 may be spaced apart from the first measuring hole HL1 in a direction opposite to a direction toward the measurement object MO and may face the first measuring hole HL1. A length L1 of the first electrostatic sensor 221 in a direction parallel to a direction in which the first measuring hole HL1 extends may be equal to or greater than the size of the first measuring hole HL1. For example, if the first measuring hole HL1 is circular, the length L1 of the electrostatic sensor 221 may be equal to or greater than the diameter D1 of the first measuring hole HL1. If the length L1 of the electrostatic sensor 221 in the direction parallel to the direction in which the first measuring hole HL1 extends is smaller than the size of the first measuring hole HL1, the first electrostatic sensor 221 may not accurately detect the static electricity of the first measurement region RM1.

The first measuring circuit 222 may measure the static electricity in the first measurement region RM1 of the first surface SF1 of the measurement object MO sensed by the first electrostatic sensor 221. The first measuring circuit 222 may include a circuit configured to measure the static electricity in the first measurement region RM1 of the first surface SF1 of the measurement object MO sensed by the first electrostatic sensor 221. The first measuring circuit 222 may be connected to the first electrostatic sensor 221. For example, the first measuring circuit 222 may include a printed circuit board (PCB), a plurality of circuit elements such as an operational amplifier (OP AMP) (not shown) provided in the circuit board PCB, a cable CB connected to the circuit board PCB, and the like. The circuit board PCB may be connected to the first electrostatic sensor 221, and the first measuring circuit 222 may be connected to the first electrostatic sensor 221. However, the configuration of the first measuring circuit 222 is not limited thereto. Because the cable CB of the first measuring circuit 222 may be earthed to ground, the first measuring circuit 222 may be earthed to ground, and because the first measuring circuit 222 may be earthed to ground, the first electrostatic measurement structure 220 may be earthed to ground separately from the first casing 210.

The second probe 300 may separate the electrostatic field caused by the static electricity of the second surface SF2, which is an opposite side to the first surface SF1 in a thickness direction of the measurement object MO, so as not to overlap the electrostatic field caused by the static electricity of the first measurement region RM1 of the first surface SF1 of the measurement object MO. The second probe 300 may separate the electrostatic field caused by the static electricity of the second surface SF2 so as not to overlap the electrostatic field caused by the static electricity of the first measurement region RM1, by making the electrostatic field caused by the static electricity of the second surface SF2 of the measurement object MO face the second probe 300, without facing the first probe 200. The second probe 300 may separate the electrostatic field caused by the static electricity of the second surface SF2 of the measurement object MO from the electrostatic field caused by the static electricity of the first measurement region RM1, and the first probe 200 may accurately measure the static electricity of the first measurement region RM1. If there is no second probe 300, the static electricity of the first measurement region RM1 measured by the first probe 200 may be inaccurate because the measured static electricity may include the static electricity of the second surface SF2. However, the second probe 300 may separate the electrostatic field caused by the static electricity of the second surface SF2 so as not to overlap the electrostatic field caused by the static electricity of the first measurement region RM1, and therefore, the first probe 200 may accurately measure the static electricity of the first measurement region RM1.

The second probe 300 may face the first probe 200 across the measurement object MO. The second probe 300 may be spaced apart from the second surface SF2 of the measurement object MO by a second distance SD2. The second distance SD2 may be smaller than the thickness T of the measurement object MO. The second distance SD2 may be the same as or different from the first distance SD1. The second distance SD2 may be equal to or less than ⅔ of the thickness T of the measurement object MO. If the second distance SD2 is greater than ⅔ of the thickness T of the measurement object MO, the second probe 300 may not properly separate the electrostatic field caused by the static electricity of the second surface SF2 from the electrostatic field caused by the static electricity of the first measurement region RM1.

The second probe 300 may be earthed to ground. The second probe 300 may be include metal or an electrostatic dissipative material. Also, as shown in FIG. 3, the electrostatic field caused by the static electricity of the second surface SF2 of the measurement object MO may face the second probe 300 without facing the first probe 200, by the second probe 300. Further, the electrostatic field caused by the static electricity of the second surface SF2 of the measurement object MO may be separated from the electrostatic field caused by the static electricity of the first measurement region RM1 without overlapping each other.

The second probe 300 may include an electrostatic field separation surface 300a. The electrostatic field separation surface 300a may face the second surface SF2. The electrostatic field separation surface 300a may face the first measuring hole HL1 of the first probe 200 across the measurement object MO. The electrostatic field separation surface 300a may be spaced apart from the second surface SF2 of the measurement object MO by the second distance SD2, and may face the second surface SF2 of the measurement object MO. The electrostatic field separation surface 300a may have a size equal to or greater than the size of the first measuring hole HL1. For example, the electrostatic field separation surface 300a and the first measuring hole HL1 may be circular, and a diameter D2 of the electrostatic field separation surface 300a may be equal to or greater than the diameter D1 of the first measuring hole HL1. If the electrostatic field separation surface 300a has a size smaller than the size of the first measuring hole HL1, the second probe 300 may not properly separate the electrostatic field caused by the static electricity of the second surface SF2 from the electrostatic field caused by the static electricity of the first measurement region RM1.

The second probe 300 may have a size and configuration different from those of the first probe 200. For example, the second probe 300 may be cylindrical, and a diameter of the second probe 300 may be smaller than a diameter of the first casing head 211 of the first probe 200. Additionally, the second probe 300 may not include a casing, such as the first casing 210 of the first probe 200.

However, in another embodiment, the second probe 300 may have the same size as the first probe 200. The second probe 300 may also include a casing such as the first casing 210 of the first probe 200.

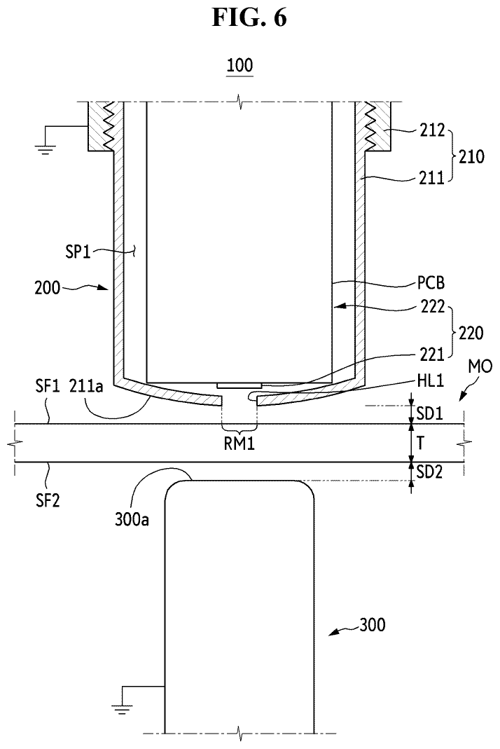

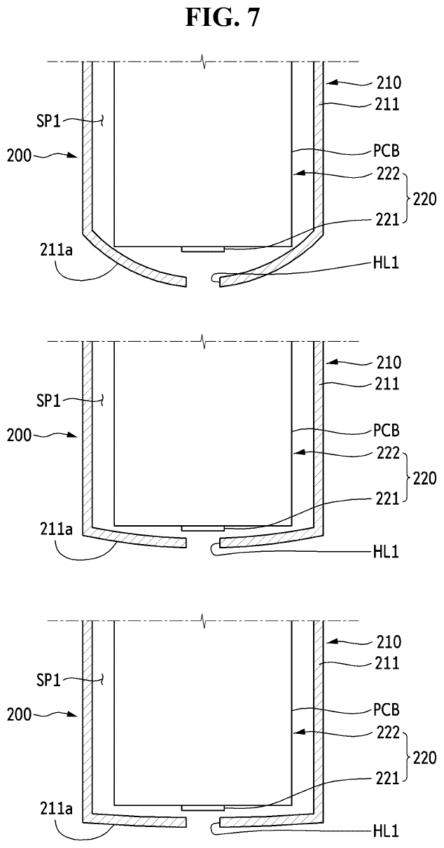

FIG. 6 is a diagram showing an apparatus for measuring static electricity according to some embodiments of the disclosure, and FIG. 7 is a diagram showing that a first measurement face of the first probe of the apparatus for measuring static electricity of FIG. 6 have different radii of curvature from each other. For convenience of explanation, the differences from the embodiments described with reference to FIGS. 1 to 5 will be mainly explained.

Referring to FIG. 6, the first sensing surface 211a of the first casing 210 may be a curved surface that is bent from the first measuring hole HL1 in the opposite direction to the direction toward the measurement object MO. The first surface SF1 of the measurement object MO may be curved rather than flat. When the first sensing surface 211a is a plane, if the first surface SF1 of the measurement object MO is bent rather than flat, the first sensing surface 211a may come into contact with the first surface SF1. However, when the first sensing surface 211a is a curved surface that is bent from the first measuring hole HL1 in the opposite direction to the direction toward the measurement object MO, even if the first surface SF1 is bent, the first sensing surface 211a may be prevented from coming into contact with the first surface SF1. Also, damage to the first surface SF1 or the measurement object MO due to contact of the first sensing surface 211a with the first surface SF1 may be prevented.

Referring to FIG. 7, a plurality of first casing heads 211 may be provided. The curvature radii of the first sensing surfaces 211a of the plurality of first casing heads 211 may be different from each other. Also, by connecting one of the first casing heads 211 having different curvature radii of the first sensing surfaces 211a to the first casing body 212, the first sensing surface 211a of the first casing 210 may have a curvature radius among various curvature radii. In other words, a curvature radius of the first sensing surface 211a of the first casing 210 may be changed. Also, the curvature radius of the first sensing surface 211a may be changed in accordance with a degree to which the first surface SF1 is bent such that the first sensing surface 211a may be prevented from coming into contact with the first surface SF1 of the measurement object MO.

Meanwhile, at least a part of the electrostatic field separation surface 300a of the second probe 300 may also be a curved surface that is bent in the opposite direction to the direction toward the measurement object MO. For example, a central part of the electrostatic field separation surface 300a of the second probe 300 may be a plane, and a portion other than the central part of the second probe 300 may be a curved surface that is bent in the opposite direction to the direction toward the measurement object MO. In another embodiment, the entire electrostatic field separation surface 300a of the second probe 300 may be a curved surface that is bent in the opposite direction to the direction toward the measurement object MO.

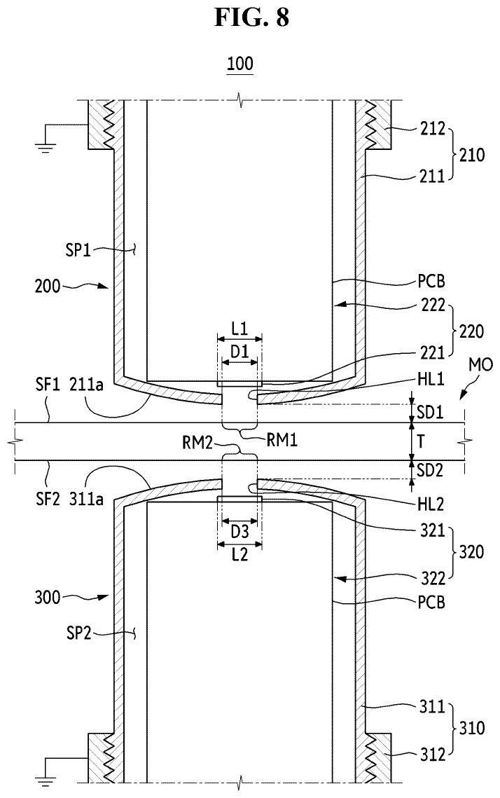

FIG. 8 is a diagram showing an apparatus for measuring static electricity according to some embodiments of the disclosure. For convenience of explanation, the differences from the embodiments described with reference to FIGS. 1 to 7 will be mainly explained.

Referring to FIG. 8, the static electricity measurement apparatus 100 may accurately measure the electrostatic distribution of the first surface SF1 and the second surface SF2 of the measurement object MO in a non-contact manner, while preventing contamination of the first surface SF1 and the second surface SF2 and the influence due to other electric fields generated outside of a measurement region. The first surface SF1 may be an upper side (or upper surface) of the measurement object MO, and the second surface SF2 may be a lower side (or lower surface) of the measurement object MO. In addition, the static electricity measurement apparatus 100 may accurately measure the electrostatic distribution of the upper side and the lower side of the measurement object MO in a non-contact manner, while preventing the contamination of the upper and lower sides of the measurement object MO and influence due to other electric fields. For example, the static electricity measurement apparatus 100 may accurately measure the electrostatic distribution of the upper side and the lower side of a substrate such as a wafer and a glass substrate in a non-contact manner, while preventing contamination of the upper and lower sides and the influence from other electric fields. The static electricity in the first measurement region RM1 on the first surface SF1 of the measurement object MO may be measured by the first probe 200 in a non-contact manner, and the static electricity in the second measurement region RM2 on the second surface SF2 may be measured by the second probe 300 in a non-contact manner.

The configuration of the first probe 200 has been described above, and therefore description thereof will not be provided below.

The second probe 300 may measure the static electricity of the second measurement region RM2 of the second surface SF2 of the measurement object MO in a non-contact manner, and the second probe 300 may not come into contact with the second surface SF2 of the measurement object MO. In addition, contamination of the second surface SF2 due to the second probe 300 may be prevented. Damage to the second surface SF2, the measurement object MO, and the like due to the second probe 300 may be prevented.

The second probe 300 may face the first probe 200 across the measurement object MO. The second probe 300 may be spaced apart from the second surface SF2 of the measurement object MO by the second distance SD2. Because the second probe 300 is spaced apart from the second surface SF2 of the measurement object MO by the second distance SD2, the electrostatic field caused by the static electricity in the second measurement region RM2 may be spaced apart from the electrostatic field caused by the static electricity in the first measurement region RM1 without overlapping each other. Furthermore, the first probe 200 may accurately measure the static electricity of the first measurement region RM1, and the second probe 300 may accurately measure the static electricity of the second measurement region RM2.

For example, the second probe 300 may be raised and lowered by a second probe elevator (not shown), and the second probe 300 is raised and lowered by the second probe elevator to be spaced apart from the second surface SF2 of the measurement object MO by the second distance SD2. The second probe 300 may be moved in the horizontal direction by a second probe mover (not shown). The second probe 300 may measure the static electricity of a plurality of second measurement regions RM2 spaced apart from each other on the second surface SF2 of the measurement object MO while being moved in the horizontal direction by the second probe mover, thereby measuring the electrostatic distribution on the second surface SF2. For example, the second probe 300 may perform a raster scan or a snake scan on the second surface SF2 of the measurement object MO by the second probe mover. Further, the second probe 300 may sequentially measure the static electricity of a plurality of second measurement regions RM2 spaced apart from each other on the second surface SF2, thereby measuring the electrostatic distribution on the second surface SF2 of the measurement object MO. Problems that may occur due to static electricity may be prevented, by utilizing the electrostatic distribution on the second surface SF2 of the measurement object MO measured in this manner.

The second distance SD2 may be smaller than the thickness T of the measurement object MO. When the second distance SD2 is smaller than the thickness T of the measurement object MO, the second probe 300 may measure the static electricity of the second measurement region RM2 in a state of being close to the second measurement region RM2 of the second surface SF2 of the measurement object MO. The second distance SD2 may be a distance that is smaller than the thickness T of the measurement object MO, but may prevent contamination or damage to the second surface SF2 of the measurement object MO by the second probe 300. Further, the second distance SD2 may be a distance that is smaller than the thickness T of the measurement object MO, but may be sufficient to prevent the adhesion of the organic material on the second surface SF2 of the measurement object MO to the second probe 300. The second distance SD2 may be equal to or less than ⅔ of the thickness T of the measurement object MO. If the second distance SD2 is greater than ⅔ of the thickness T of the measurement object MO, the electrostatic field caused by the static electricity of the second measurement region RM2 of the measurement object MO may not sufficiently reach the second probe 300. In addition, the measurement of the static electricity of the second measurement region RM2 of the measurement object MO by the second probe 300 may not be accurate. For example, the measurement object MO is a substrate having a thickness T of 775 μm, the second distance SD2 may be about 80 μm to 100 μm. The second probe 300 includes a second casing 310, a second electrostatic measurement structure 320 and the like.

The second casing 310 may provide an external shape of the second probe 300, and may support the second electrostatic measurement structure 320 and protect the second electrostatic measurement structure 320 from the outside. The second casing 310 may be earthed to ground. Since the second casing 310 may be earthed to ground, the second electrostatic measurement structure 320 may not be affected by electric fields other than the electrostatic field caused by the static electricity of the second measurement region RM2 of the second surface SF2 of the measurement object MO. That is to say, electric fields other than the electrostatic field caused by the static electricity of the second measurement region RM2 of the measurement object MO may face a region of the second casing 310 other than a second measuring hole HL2, not toward the second measuring hole HL2 that corresponds the second measurement region RM2. In addition, the electrostatic measurement of the second measurement region RM2 of the measurement object MO by the second electrostatic measurement structure 320 may be accurate. The second casing 310 may include a metal or an electrostatic dissipative material. The second casing 310 may include the second measuring hole HL2 and a second space SP2.

The second measuring hole HL2 may correspond to a position of a second measurement region RM2 on the second surface SF2 of the measurement object MO. The second measuring hole HL2 may face the second surface SF2 to form the second measurement region RM2. In other words, a portion of the second surface SF2 to which the second measuring hole HL2 faces may be the second measurement region RM2. The second measuring hole HL2 may be spaced apart from the second surface SF2 by the second distance SD2, and may face the second surface SF2 to form the second measurement region RM2. The second measuring hole HL2 may face the first measuring hole HL1 of the first probe 200 across the measurement object MO. In addition, the second measurement region RM2 may face the first measurement region RM1 in the measurement object MO. The electrostatic field caused by the static electricity in the second measurement region RM2 may be sensed by a second electrostatic sensor 321 of the second electrostatic measurement structure 320 through the second measuring hole HL2, thereby measuring the electrostatic field of the second measurement region RM2. As described above, since the second casing 310 may be earthed to ground, the electric field other than the second measurement region RM2 of the measurement object MO may face a region of the second casing 310 other than the second measuring hole HL2, without facing the second measuring hole HL2. In addition, the second electrostatic sensor 321 may not sense the electric field other than the second measurement region RM2 of the measurement object MO.

The second measuring hole HL2 may have a size which is large enough that the second electrostatic sensor 321 of the second electrostatic measurement structure 320 may sense the static electricity of the second measurement region RM2 of the measurement object MO. The second measuring hole HL2 may have a size that is equal to or greater than 1/10 of the thickness T of the measurement object MO. If the size of the second measuring hole HL2 is smaller than 1/10 of the thickness T of the measurement object MO, the second electrostatic sensor 321 may not or may not sufficiently sense the static electricity of the second measurement region RM2. For example, if the second measuring hole HL2 is circular, a diameter D3 of the second measuring hole HL2 may be equal to or greater than 1/10 of the thickness T of the measurement object MO.

As it will be described below, the size of the second measuring hole HL2 may change. As the size of the second measuring hole HL2 changes, the size of the second measurement region RM2 of the measurement object MO may also change. When the size of the second measuring hole HL2 increases, the size of the second measurement region RM2 also increases, and a magnitude of potential or the like of the static electricity measured by the second electrostatic measurement structure 320 may increase. However, a spatial resolution of the second probe 300 may increase. Also, when the size of the second measuring hole HL2 decreases, the size of the second measurement region RM2 decreases, and the magnitude of potential or the like of the static electricity measured by the second electrostatic measurement structure 320 may decrease. However, the spatial resolution of the second probe 300 may decrease. Taking this into consideration, the size of the second measuring hole HL2 may be selected in accordance with desired measurement conditions. For example, if the measurement object MO is a substrate having a diameter of about 300 mm, the size of the second measuring hole HL2 may be selected such that the magnitude of potential of the static electricity of the second measurement region RM2 measured by the second electrostatic measurement structure 320 is also sufficiently large, and the spatial resolution becomes 0.5 mm to 3 mm. On the other hand, even if the spatial resolution is larger than a predetermined condition or a number of the second measurement regions RM2 is smaller than a predetermined number, a desired electrostatic distribution on the second surface SF2 of the measurement object MO may be obtained, by utilizing a super-resolution technique using a Gaussian distribution. The second measuring hole HL2 may be formed in a second casing head 311 of the second casing 310, which will be described below.

The second electrostatic measurement structure 320 may be disposed in the second space SP2. The second space SP2 may communicate with the second measuring hole HL2. Also, the second electrostatic sensor 321 of the second electrostatic measurement structure 320 may sense static electricity in the second measurement region RM2 of the second surface SF2 of the measurement object MO through the second measuring hole HL2. The second space SP2 may be formed in the second casing head 311 and the second casing body 312 of the second casing 310.

The second casing 310 may include the second casing head 311, the second casing body 312, and the like.

The second casing head 311 may be spaced apart from the second surface SF2 of the measurement object MO by the second distance SD2. The second casing head 311 may have the second measuring hole HL2 formed therein. A part of the second electrostatic measurement structure 320, such as the second electrostatic sensor 321 of the second electrostatic measurement structure 320, may be disposed in the second casing head 311.

The second casing head 311 may be detachably connected to the second casing body 312. For example, a male screw thread may be formed in the second casing head 311, and a female screw thread may be formed in the second casing body 312, such that the second casing head 311 may be detachably connected to the second casing body 312. However, the configuration in which the second casing head 311 is detachably connected to the second casing body 312 is not limited thereto.

A plurality of second casing heads 311 may be provided. The second measuring holes HL2 of the plurality of second casing heads 311 may have different sizes from each other. In addition, by connecting one of the second casing heads 311 having different sizes of the second measuring holes HL2 to the second casing body 312, the second measuring holes HL2 of the second casing 310 may have various sizes. In other words, the size of the second measuring hole HL2 of the second casing 310 may be changed. In addition, the size of the second measuring hole HL2 may be changed in accordance with desired measurement conditions. The second casing head 311 may have a cylindrical shape. However, the shape of the second casing head 311 is not limited thereto.

The second casing head 311 may include a second sensing surface 311a. The second sensing surface 311a faces the second surface SF2 of the measurement object MO, and may have a second measuring hole HL2 formed therein. The second sensing surface 311a may face the first sensing surface 211a of the first probe 200 across the measurement object MO. The second sensing surface 311a may be a curved surface that is bent from the second measuring hole HL2 in the direction opposite to the direction toward the measurement object MO. However, in another embodiment, the second sensing surface 311a may be a plane.

The second casing body 312 may be detachably connected to the second casing head 311 to support the second casing head 311. Other parts of the second electrostatic measurement structure 320, such as a second measuring circuit 322 of the second electrostatic measurement structure 320 to be described below, may be disposed in the second casing body 312. The second casing body 312 may have a linear rod shape. However, the shape of the second casing body 312 is not limited thereto, and may have various shapes such as an “L” or “U” shaped rod shape.

The second electrostatic measurement structure 320 may measure static electricity in the second measurement region RM2 of the second surface SF2 of the measurement object MO. The second electrostatic measurement structure 320 may be disposed in the second casing 310. The second electrostatic measurement structure 320 may be disposed in the second space SP2 of the second casing 310. The second electrostatic measurement structure 320 may be earthed to ground separately from the second casing 310. Because the second electrostatic measurement structure 320 may be earthed to ground separately from the second casing 310, the second electrostatic measurement structure 320 may measure static electricity in the second measurement region RM2 of the measurement object MO without being affected by the second casing 310. The second electrostatic measurement structure 320 may include the second electrostatic sensor 321 and the second measuring circuit 322.

The second electrostatic sensor 321 may sense the static electricity in the second measurement region RM2 of the second surface SF2 of the measurement object MO through the second measuring hole HL2. The static electricity in the second measurement region RM2 sensed by the second electrostatic sensor 321 may be measured by the second measuring circuit 322. The second electrostatic sensor 321 may be spaced apart from the second measuring hole HL2 in a direction opposite to the direction toward the measurement object MO, and may face the second measuring hole HL2. A length L2 of the second electrostatic sensor 321 may be a direction parallel to a direction in which the second measuring hole HL2 extends may be equal to or greater than the size of the second measuring hole HL2. For example, if the second measuring hole HL2 is circular, the length L2 of the second electrostatic sensor 321 may be equal to or greater than the diameter D3 of the second measuring hole HL2. If the length L2 of the second electrostatic sensor 321 in the direction parallel to the direction in which the second measuring hole HL2 extends is smaller than the size of the second measuring hole HL2, the second electrostatic sensor 321 may not correctly detect the static electricity of the second measurement region RM2.

The second measuring circuit 322 may measure the static electricity in the second measurement region RM2 of the second surface SF2 of the measurement object MO sensed by the second electrostatic sensor 321. The second measuring circuit 322 may include a circuit configured to measure the static electricity in the second measurement region RM2 of the second surface SF2 of the measurement object MO sensed by the second electrostatic sensor 321. The second measuring circuit 322 may be connected to the second electrostatic sensor 321. For example, the second measuring circuit 322 may include a circuit board PCB, a plurality of circuit elements such as an operational amplifier (not shown) provided on the circuit board PCB, a cable CB connected to the circuit board PCB, and the like. Further, the circuit board PCB may be connected to the second electrostatic sensor 321, and the second measuring circuit 322 may be connected to the second electrostatic sensor 321. However, the configuration of the second measuring circuit 322 is not limited thereto. Since the cable CB of the second measuring circuit 322 may be earthed to ground, the second measuring circuit 322 may be earthed to ground, and since the second measuring circuit 322 may be earthed to ground, the second electrostatic measurement structure 320 may be earthed to ground separately from the second casing 310.

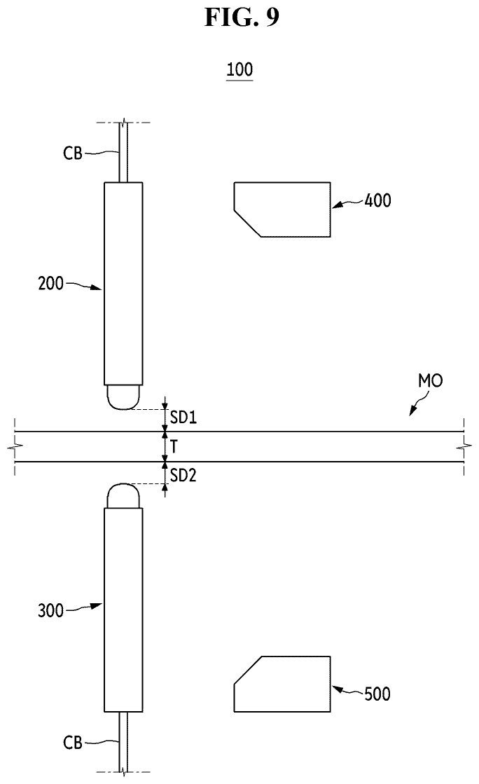

FIG. 9 is a diagram showing an apparatus for measuring static electricity according to some embodiments of the disclosure. For convenience of explanation, differences from the embodiments described with reference to FIGS. 1 to 8 will be mainly explained.

Referring to FIG. 9, the static electricity measurement apparatus 100 may further include a first distance measurer 400 and a second distance measurer 500.

The first distance measurer 400 may be spaced apart from the first surface SF1 of the measurement object MO, and may measure a distance to the first surface SF1. The first distance measurer 400 may measure a distance between the first probe 200 and the first surface SF1. For example, the first distance measurer 400 may be a laser distance measurer, a confocal distance measurer, an interferometer distance measurer, a vision distance measurer or the like.

The first distance measurer 400 may measure the distance between the first probe 200 and the first surface SF1, while being raised and lowered by the first probe elevator together with the first probe 200. For example, when the first probe 200 comes into contact with the first surface SF1, the distance to the first surface SF1 measured by the first distance measurer 400 may be used as a reference distance. Also, the distance between the first probe 200 and the first surface SF1 may be measured, by subtracting the distance to the first surface SF1 measured by the first distance measurer 400 from the reference distance, when the first probe 200 is spaced apart from the first surface SF1.

The first distance measurer 400 may be moved in a horizontal direction by the first probe mover or a first measurer mover (not shown), while being spaced apart from the first surface SF1 of the measurement object MO by a predetermined distance. Also, the first distance measurer 400 may measure a shape of the first surface SF1 by measuring a distance to each of a plurality of positions spaced apart from each other on the first surface SF1. For example, the first distance measurer 400 may perform a raster scan or a snake scan on the first surface SF1 of the measurement object MO by movement in the horizontal direction by the first probe mover or the first measurer mover. The first distance measurer 400 may measure the shape of the first surface SF1, by sequentially measuring the distance to each of the plurality of positions spaced apart from each other on the first surface SF1.

Otherwise, the first distance measurer 400 may measure the shape of the first surface SF1 by performing a vision scan on the first surface SF1, while being spaced apart from the first surface SF1 of the measurement object MO by a predetermined distance.

The first probe 200 may be spaced apart from the first surface SF1 by the first distance SD1 by the first probe elevator, using the distance between the first probe 200 and the first surface SF1 and/or the shape of the first surface SF1, measured by the first distance measurer 400.

The second distance measurer 500 may be spaced apart from the second surface SF2 of the measurement object MO, and may measure a distance to the second surface SF2. The second distance measurer 500 may measure a distance between the second probe 300 and the second surface SF2. For example, the second distance measurer 500 may be a laser distance measurer, a confocal distance measurer, an interferometer distance measurer, a vision distance measurer or the like.

The second distance measurer 500 may measure the distance between the second probe 300 and the second surface SF2, while being raised and lowered together with the second probe 300 by the second probe elevator. For example, when the second probe 300 comes into contact with the second surface SF2, the distance to the second surface SF2 measured by the second distance measurer 500 may be used as the reference distance. In addition, the distance between the second probe 300 and the second surface SF2 may be measured, by subtracting the distance to the second surface SF2 measured by the first distance measurer 400 from the reference distance, when the second probe 300 is spaced apart from the second surface SF2.

The second distance measurer 500 may be moved in the horizontal direction by the second probe mover or a second measurer mover (not shown), while being spaced apart from the second surface SF2 of the measurement object MO by a predetermined distance. The second distance measurer 500 may measure a shape of the second surface SF2 by measuring the distance to each of a plurality of positions spaced apart from each other on the second surface SF2. For example, the second distance measurer 500 may perform a raster scan or a snake scan on the second surface SF2 of the measurement object MO, by movement in the horizontal direction by the second probe mover or the second measurer mover. In addition, the second distance measurer 500 may measure the shape of the second surface SF2, by sequentially measuring the distance to each of the plurality of positions spaced apart from each other on the second surface SF2.

The second distance measurer 500 may measure the shape of the second surface SF2 by performing the vision scan on the second surface SF2, while being spaced apart from the second surface SF2 of the measurement object MO by a predetermined distance. The second probe 300 may be spaced apart from the second surface SF2 by the second distance SD2 by the second probe elevator, using the distance between the second probe 300 and the second surface SF2 and/or the shape of the second surface SF2, measured by the second distance measurer 500.

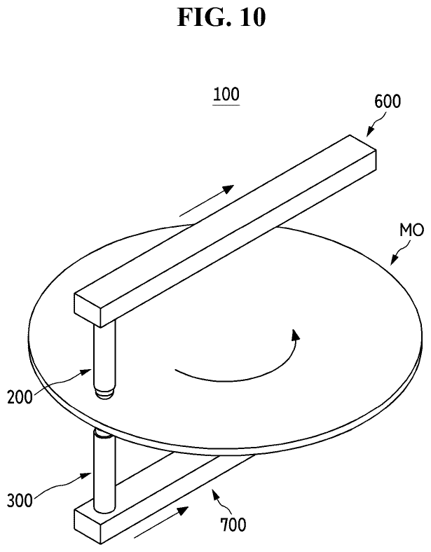

FIG. 10 is a diagram showing an apparatus for measuring static electricity according to some embodiments of the disclosure, and measurement of the electrostatic distribution of the first surface or the first surface and the second surface of the measurement object, using the same. For convenience of explanation, differences from the embodiments described with reference to FIGS. 1 to 9 will be mainly explained.

Referring to FIG. 10, the first probe 200 may be disposed in a first probe holder 600, and the second probe 300 may be disposed in a second probe holder 700. In addition, the first probe holder 600 may be moved in the horizontal direction by a first holder mover (not shown), and the second probe holder 700 may be moved in the horizontal direction by a second holder mover (not shown). The measurement object MO may be rotated by an object rotator (not shown).

The measurement object MO may be rotated by the object rotator, the first probe holder 600 and the second probe holder 700 may be moved in the horizontal direction, and the electrostatic distribution of the first surface SF1, or the first surface SF1 and the second surface SF2, of the measurement object MO may be measured by the first probe 200 and the second probe 300. That is to say, the static electricity of a plurality of first measurement regions RM1 spaced apart from each other on the first surface SF1 of the measurement object MO may be measured sequentially, or the static electricity of a plurality of second measurement regions RM2 spaced apart from each other on the second surface SF2 of the measurement object MO may be measured sequentially. Alternatively, the static electricity of a plurality of first measurement regions RM1 spaced apart from each other on the first surface SF1 of the measurement object MO and the static electricity of a plurality of second measurement regions RM2 spaced apart from each other on the second surface SF2 of the measurement object MO may be measured sequentially.

For example, the measurement object MO may be rotated by the object rotor, and the static electricity of a plurality of measurement regions RM1 and RM2 of the first surface SF1, or the first surface SF1 and the second surface SF2, of the measurement object MO may be measured sequentially in a circumferential direction of the measurement object MO. Also, the first probe holder 600 and the second probe holder 700 may be moved in the horizontal direction, and the static electricity of the plurality of measurement regions RM1 and RM2 of the first surface SF1, or the first surface SF1 and the second surface SF2, of the measurement object MO may be measured sequentially from the outside to the inside in the radial direction of the measurement object MO.

The first probe holder 600 may be rotated around a center of the first probe holder 600 by a first holder rotator (not shown), and the second probe holder 700 may be rotated around a center of the second probe holder 700 by a second holder rotator (not shown). The measurement object MO may be moved in the horizontal direction by an object mover (not shown). In addition, each of the first probe holder 600 and the second probe holder 700 may be rotated by the first holder rotator and the second holder rotator, respectively, the measurement object MO may be moved in the horizontal direction by the measurement object mover, and the electrostatic distribution of the first surface SF1, or the first surface SF1 and the second surface SF2, of the measurement object MO may be measured by the first probe 200 and the second probe 300.

Meanwhile, although not shown, the first probe elevator for raising and lowering the first probe 200 may be disposed in the first probe holder 600, and the second probe elevator for raising and lowering the second probe 300 may be disposed in the second probe holder 700. Although not shown, the static electricity measurement apparatus 100 may include the first distance measurer 400 and the second distance measurer 500 as shown in FIG. 9.

The shapes of the first surface SF1 and the second surface SF2 of the measurement object MO may be measured by the first distance measurer 400 and the second distance measurer 500, respectively. Further, the first probe 200 may be spaced apart from the first surface SF1 by the first distance SD1 by the first probe mover, and the second probe 300 may be spaced apart from the second surface SF2 by the second distance SD2 by the second probe mover, using the shapes of the first surface SF1 and the second surface SF2 of the measurement object MO. The static electricity of the first measurement region RM1 of the first surface SF1 of the measurement object MO or the first measurement region RM1 of the first surface SF1 and the second measurement region RM2 of the second surface SF2 may be measured by the first probe 200 and the second probe 300.

The shapes of the first surface SF1 and the second surface SF2 of the measurement object MO may not be measured by the first distance measurer 400 and the second distance measurer 500. The first distance measurer 400 may measure the distance between the first probe 200 and the first surface SF1 of the measurement object MO, and the second distance measurer 500 may measure the distance between the second probe 300 and the second surface SF2 of the measurement object MO. Also, the first probe 200 may be spaced apart from the first surface SF1 by the first distance SD1 by the first probe mover, and the second probe 300 may be spaced apart from the second surface SF2 by the second distance SD2 by the second probe mover. The static electricity of the first measurement region RM1 of the first surface SF1 of the measurement object MO or the first measurement region RM1 of the first surface SF1 and the second measurement region RM2 of the second surface SF2 may be measured by the first probe 200 and the second probe 300.

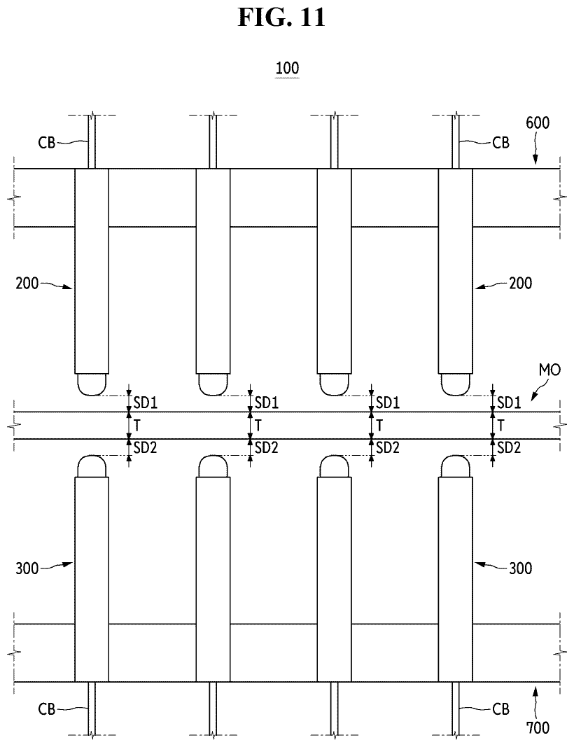

FIG. 11 is a diagram showing an apparatus for measuring static electricity according to some embodiments of the disclosure. For convenience of explanation, differences from the embodiments described with reference to FIGS. 1 to 10 will be mainly explained.

Referring to FIG. 11, a plurality of first probes 200 may be provided and spaced apart from each other. For example, the plurality of first probes 200 may be disposed on the first probe holder 600 to be spaced apart from each other in the horizontal direction. Each of the plurality of first probes 200 may simultaneously measure the static electricity of a corresponding one of the plurality of first measurement regions RM1 spaced apart from each other on the first surface SF1 of the measurement object MO. In other words, at least a part of the electrostatic distribution on the first surface SF1 may be measured at once by the plurality of first probes 200.

The plurality of first probes 200 may each be raised and lowered by the plurality of first probe elevators. The plurality of first probes 200 may be moved together in the horizontal direction. For example, the plurality of first probes 200 may be moved together in the horizontal direction by the horizontal movement of the first probe holder 600 by the first holder mover.

When the plurality of first probes 200 are provided, a plurality of first distance measurers 400 as shown in FIG. 9 may be provided. Each of the plurality of first distance measurers 400 may measure the distance between a corresponding one of the plurality of first probes 200 and the first surface SF1 of the measurement object MO. Each of the plurality of first probes 200 may be spaced apart from the first surface SF1 by the first distance SD1 by each of the plurality of first probe elevators. Each of the plurality of first probes 200 may simultaneously measure the static electricity of a corresponding one of the plurality of first measurement regions RM1 spaced apart from each other on the first surface SF1 of the measurement object MO. In another embodiment, a single first distance measurer 400 may be provided. The single first distance measurer 400 may measure the shape of the first surface SF1 of the measurement object MO. Each of the plurality of first probes 200 may be spaced apart from the first surface SF1 by the first distance SD1 by each of the plurality of first probe elevators, using the shape of the first surface SF1. Each of the plurality of first probes 200 may simultaneously measure the static electricity of a corresponding one of the plurality of first measurement regions RM1 spaced apart from each other on the first surface SF1 of the measurement object MO.

When the plurality of first probes 200 are provided in this way, time required to measure the electrostatic distribution of the first surface SF1 of the measurement object MO may be shortened.

A plurality of second probes 300 are provided, and may be spaced apart from each other. For example, the plurality of second probes 300 may be disposed on the second probe holder 700 to be spaced apart from each other in the horizontal direction. Each of the plurality of second probes 300 may simultaneously measure the static electricity of a corresponding one of the plurality of second measurement regions RM2 spaced apart from each other on the second surface SF2 of the measurement object MO. In other words, at least a part of the electrostatic distribution of the second surface SF2 may be measured at once by the plurality of second probes 300.

Each of the plurality of second probes 300 may be raised and lowered by the plurality of second probe elevators. The plurality of second probes 300 may be moved together in the horizontal direction. For example, the plurality of second probes 300 may be moved together in the horizontal direction by the horizontal movement of the second probe holder 700 by the second holder mover.

When the plurality of second probes 300 are provided, a plurality of second distance measurers 500 as shown in FIG. 9 may also be provided. Each of the plurality of second distance measurers 500 may measure the distance between a corresponding one of the plurality of second probes 300 and the second surface SF2 of the measurement object MO. Each of the plurality of second probes 300 may be spaced apart from the second surface SF2 by the second distance SD2 by the plurality of second probe elevators. Each of the plurality of second probes 300 may simultaneously measure the static electricity of a corresponding one of the plurality of second measurement regions RM2 spaced apart from each other on the second surface SF2 of the measurement object MO.

In another embodiment, a single second distance measurer 500 may be provided. The single second distance measurer 500 may measure the shape of the second surface SF2 of the measurement object MO. Each of the plurality of second probes 300 may be spaced apart from the second surface SF2 by the second distance SD2 by each of the plurality of second probe elevators, using the shape of the second surface SF2. Each of the plurality of second probes 300 may simultaneously measure the static electricity of a corresponding of the plurality of second measurement regions RM2 spaced apart from each other on the second surface SF2 of the measurement object MO.

In this way, when the plurality of second probes 300 are provided, time required to measure the electrostatic distribution of the second surface SF2 of the measurement object MO may be shortened.

On the other hand, when the electrostatic distribution of the second surface SF2 of the measurement object MO is not measured, the single second probe 300 may be provided, earthed to ground, and may include a metal or an electrostatic dissipative material. The second probe 300 may separate the electrostatic field caused by the static electricity of the plurality of first measurement regions RM1 and the electrostatic field caused by the static electricity of the second surface SF2 of the measurement object MO so as not to overlap each other.

In another embodiment, if the electrostatic distribution on the second surface SF2 of the measurement object MO is not measured, the plurality of second probes 300 may be provided, and may be spaced apart from each other. Furthermore, the plurality of second probes 300 may be earthed to ground, and include a metal or an electrostatic dissipative material.

A number of the second probe 300 may be the same as a number of the first probe 200. Each second probe 300 may separate the electrostatic field caused by the static electricity of one of the plurality of first measurement regions RM1, and the electrostatic field caused by the static electricity of a region of the second surface SF2 of the measurement object MO corresponding to the one of the plurality of first measurement regions RM1 so as not to overlap each other.

The number of the second probe 300 may be smaller than the number of the first probe 200. Each second probe 300 may separate the electrostatic field caused by the static electricity of a portion of the plurality of first measurement regions RM1, and the electrostatic field caused by the static electricity of a region of the second surface SF2 of the measurement object MO corresponding to the portion of the plurality of first measurement regions RM1 so as not to overlap each other.

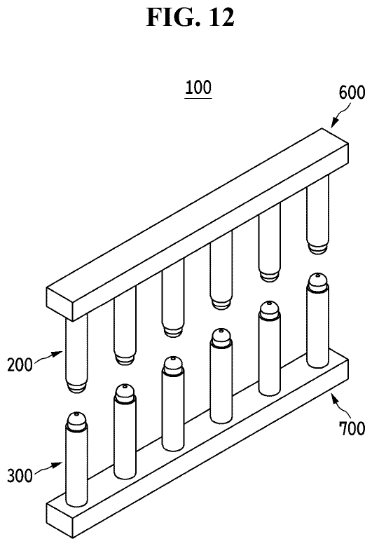

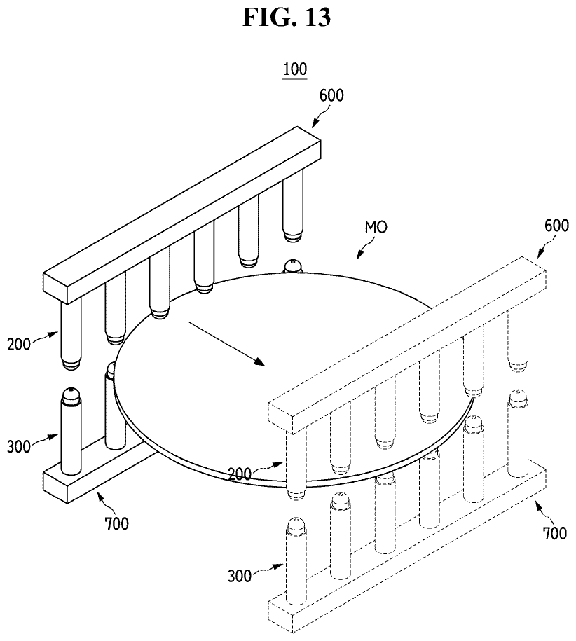

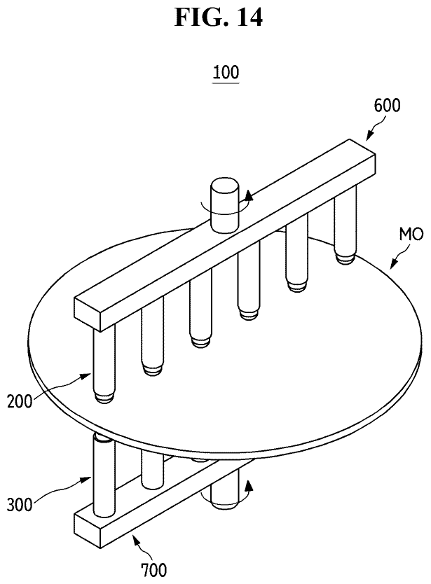

FIG. 12 is a diagram showing an apparatus for measuring static electricity according to some embodiments of the disclosure, FIG. 13 is a diagram showing an example of measuring the electrostatic distribution of the first surface or the first surface and the second surface of the measurement object by the apparatus for measuring static electricity of FIG. 12, and FIG. 14 is a diagram showing another example of measuring the electrostatic distribution of the first surface or the first surface and the second surface of the measurement object by the apparatus for measuring static electricity of FIG. 12. For convenience of explanation, differences from the embodiments described with reference to FIGS. 1 to 11 will be mainly explained.

Referring to FIG. 12, the first probe holder 600 and the second probe holder 700 may each have a bar shape. The plurality of first probes 200 may be disposed on the bar-shaped first probe holder 600 to be spaced apart from one another in a longitudinal direction of the first probe holder 600. The plurality of second probes 300 may be disposed on the bar-shaped second probe holder 700 to be spaced apart from one another in a longitudinal direction of the second probe holder 700.

Referring to FIG. 13, the first probe holder 600 may be moved in the horizontal direction by the first holder mover, and the second probe holder 700 may be moved in the horizontal direction by the second holder mover. At least some of the electrostatic distribution on the first surface SF1 or the first surface SF1 and the second surface SF2 of the measurement object MO may be measured by the plurality of first probes 200 and the plurality of second probes 300.

In another embodiment, the first probe holder 600 and the second probe holder 700 may not move in the horizontal direction, the measurement object MO may be moved in the horizontal direction by the measurement object mover, and at least some of the electrostatic distribution on the first surface SF1 or the first surface SF1 and the second surface SF2 of the measurement object MO may be measured by the plurality of first probes 200 and the plurality of second probes 300.

Referring to FIG. 14, the bar-shaped first probe holder 600 may be rotated around the center of the first probe holder 600 by the first holder rotator, and the bar-shaped second probe holder 700 may be rotated around the center of the second probe holder 700 by the second holder rotator. Also, at least some of the electrostatic distribution on the first surface SF1, or the first surface SF1 and the second surface SF2, of the measurement object MO may be measured by the plurality of first probes 200 and the plurality of second probes 300.

In another embodiment, the first probe holder 600 and the second probe holder 700 may not be rotated, the measurement object MO may be rotated around the center of the measurement object MO by the object rotator, and at least some of the electrostatic distribution on the first surface SF1, or the first surface SF1 and the second surface SF2, of the measurement object MO may be measured by the plurality of first probes 200 and the plurality of second probes 300.

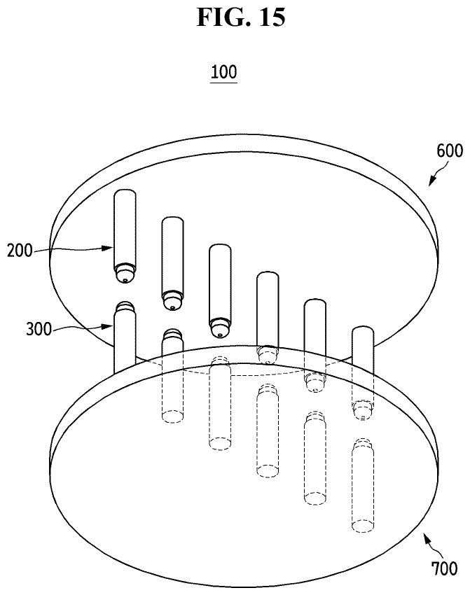

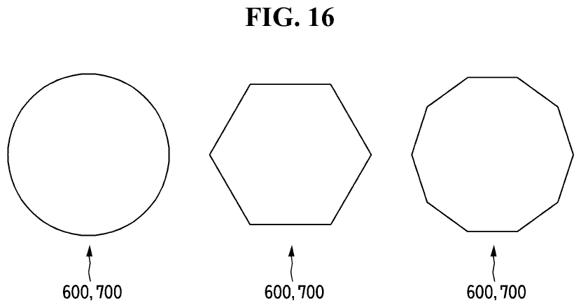

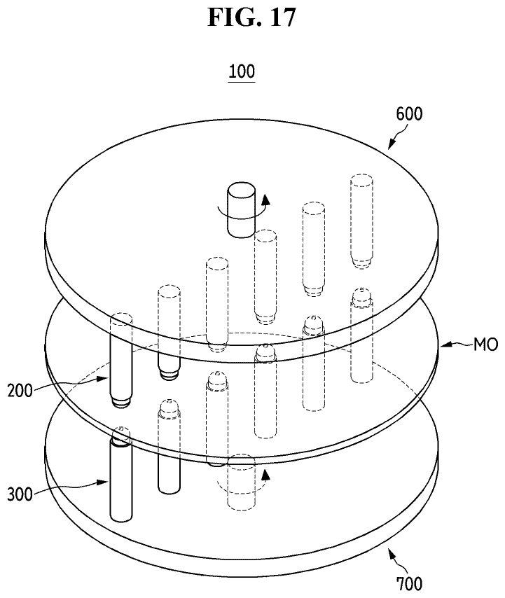

FIG. 15 is a diagram showing an apparatus for measuring static electricity according to some embodiments of the disclosure, FIG. 16 is a diagram showing various shapes of the first probe holder and the second probe holder of the apparatus for measuring static electricity of FIG. 15, and FIG. 17 is a diagram showing the measurement of the electrostatic distribution on the first surface or the first surface and the second surface of the measurement object by the apparatus for measuring static electricity of FIG. 15. For convenience of explanation, differences from the embodiments described provided with reference to FIGS. 1 to 14 will be mainly explained.

Referring to FIGS. 15 and 16, the first probe holder 600 and the second probe holder 700 may have a plate shape. For example, the first probe holder 600 and the second probe holder 700 may have a disk shape, or may have a polygonal plate shape such as a hexagonal plate or a decagonal plate.

The plurality of first probes 200 may be spaced apart from one another along a virtual line passing through a center of the plate-shaped first probe holder 600. The plurality of second probes 300 may be spaced apart from one another along a virtual line passing through a center of the plate-shaped second probe holder 700.

Referring to FIG. 17, the plate-shaped first probe holder 600 may be rotated around the center of the first probe holder 600 by the first holder rotator, and the plate-shaped second probe holder 700 may be rotated around the center of the second probe holder 700 by the second holder rotator. At least some of the electrostatic distribution of the first surface SF1, or the first surface SF1 and the second surface SF2, of the measurement object MO may be detected by the plurality of first probes 200 and the plurality of second probes 300.

In another embodiment, the first probe holder 600 and the second probe holder 700 may not be rotated, and the measurement object MO may be rotated around the center of the measurement object MO by an object rotator, and at least some of the electrostatic distribution of the first surface SF1, or the first surface SF1 and the second surface SF2, of the measurement object MO may be measured by the plurality of first probes 200 and the plurality of second probes 300.

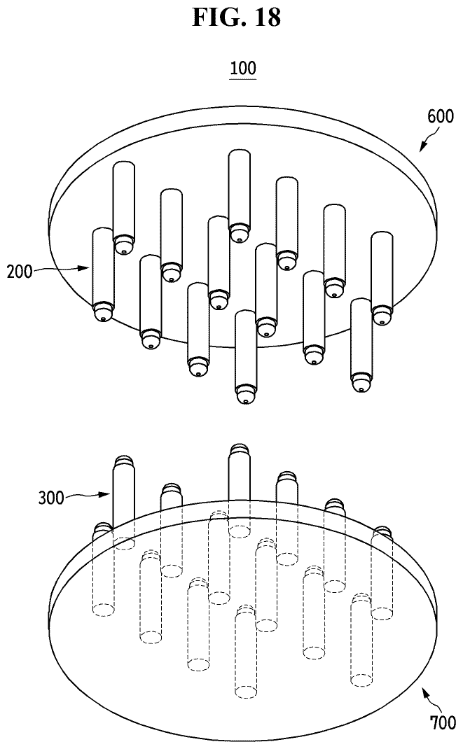

FIG. 18 is a diagram showing an apparatus for measuring static electricity according to some embodiments of the disclosure. For convenience of explanation, differences from the embodiments described with reference to FIGS. 1 to 17 will be mainly explained.

Referring to FIG. 18, the plurality of first probes 200 may be disposed on the plate-shaped first probe holder 600 to be spaced apart from each other. The plurality of second probes 300 may be spaced apart from each other on the plate-shaped second probe holder 700. At least some of the electrostatic distribution of the first surface SF1, or the first surface SF1 and the second surface SF2, of the measurement object MO may be measured at once.

In such a case, the number of the plurality of first probes 200 may be the same as the number of the plurality of first measurement regions RM1 on the first surface SF1 of the measurement object MO. The number of plurality of the second probes 300 may be the same as the number of the plurality of second measurement regions RM2 on the second surface SF2 of the measurement object MO. The electrostatic distribution on the first surface SF1, or the first surface SF1 and the second surface SF2, of the measurement object MO may be measured at once.

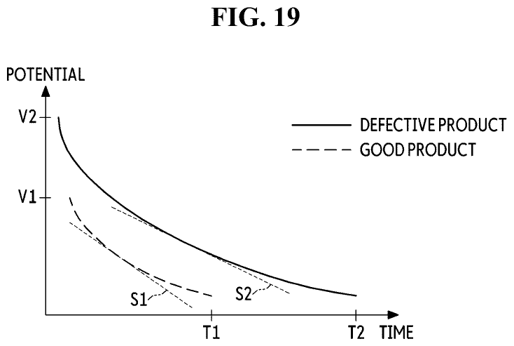

FIG. 19 is a graph showing that the static electricity of different measurement regions on the first surface or the second surface of the measurement object is measured simultaneously over time by the apparatus for measuring static electricity according to some embodiments of the disclosure, and one measurement region is a defective product and the other measurement region is a good product.

Referring to FIG. 19, when the plurality of first probes 200 and the plurality of second probes 300 are provided, the static electricity of different measurement regions RM1 and RM2 on the first surface SF1 or the second surface SF2 of the measurement object MO may be measured simultaneously over time.

On the other hand, potential of the static electricity of the surfaces SF1 and SF2 of the measurement object MO may decrease over time due to release of charges from the surfaces SF1 and SF2. Further, a pattern in which the potential of the static electricity and the static electricity at a beginning of the static electricity measurement decreases over time may vary depending on whether a portion of the measurement object MO is a good (or non-defective) product or a defective product.

A part of the measurement object MO may be a defective product and the other part may be a good product. As shown in FIG. 19, at the beginning of the static electricity measurement, a potential V2 of the static electricity of the measurement regions RM1 and RM2 of the defective portion of the measurement object MO may be greater than a potential V1 of the static electricity of the measurement regions RM1 and RM2 of the good portion.

The charge may remain on the surface of the defective portion of the measurement object MO for a longer period than the surface of the good portion. Further, time T2 required for the potential of the measurement regions RM1 and RM2 of the defective portion of the measurement object MO to decrease to a predetermined potential may be greater than time T1 required for the potential of the measurement regions RM1 and RM2 of the good portion to decrease to the predetermined potential.

A rate of decrease S2 of the potential of the static electricity of the measurement regions RM1 and RM2 in the defective portion of the measurement object MO over time may be smaller than a rate of decrease S1 of the potential of the static electricity of the measurement regions RM1 and RM2 in the good portion over time.

Further, by simultaneously measuring the static electricity of the different measurement regions RM1 and RM2 of the first surface SF1 or the second surface SF2 of the measurement object MO over time using the plurality of first probes 200 and the plurality of second probes 300, it is possible to predict whether the portion of the measurement object MO is a good product or a defective product.

Although example embodiments of the disclosure have been described with reference to the accompanying drawings, the disclosure is not limited to the above embodiments, but may be implemented in various different forms. A person skilled in the art may appreciate that the disclosure may be practiced in other concrete forms without changing the technical spirit or essential characteristics of the disclosure. Therefore, it should be appreciated that the embodiments as described above are not restrictive but illustrative in all respects.

What is claimed is:

1. An apparatus for measuring a static electricity, comprising:
a first probe spaced apart from a first surface of a measurement object by a first distance; and
a second probe spaced apart from a second surface by a second distance, the second surface opposing the first surface in a thickness direction of the measurement object,
wherein the first probe includes:
a first casing; and
a first electrostatic measurement structure provided in the first casing, and configured to measure a static electricity in a first measurement region included in the first surface,
wherein the first distance and the second distance are smaller than a thickness of the measurement object,
wherein the first casing is earthed to a ground, and
wherein the first electrostatic measurement structure is earthed to the ground separately from the first casing.

2. The apparatus for measuring static electricity of claim 1, wherein each of the first distance and the second distance is equal to or less than ⅔ of the thickness.

3. The apparatus for measuring static electricity of claim 1, wherein the first casing includes a first measuring hole that faces the first surface and corresponds to the first measurement region.

4. The apparatus for measuring static electricity of claim 3, wherein the first casing includes:
a first casing head, which includes the first measuring hole thereon; and
a first casing body to which the first casing head is detachably connected.

5. The apparatus for measuring static electricity of claim 3, wherein the first electrostatic measurement structure includes a first electrostatic sensor that is spaced apart from the first measuring hole in a direction opposite to a direction toward the measurement object and faces the first measuring hole, and
wherein a length of the first electrostatic sensor in a direction parallel to a first direction in which the first measuring hole extends is equal to or greater than a length of the first measuring hole in the first direction.

6. The apparatus for measuring static electricity of claim 3, wherein the first casing includes a first sensing surface that faces the first surface and includes the first measuring hole thereon.

7. The apparatus for measuring static electricity of claim 6, wherein the first sensing surface includes a curved surface that is bent from the first measuring hole in a direction opposite to a direction toward the measurement object.

8. The apparatus for measuring static electricity of claim 1, wherein the first casing includes a metal or an electrostatic dissipative material.

9. The apparatus for measuring static electricity of claim 1, wherein the second probe is earthed to the ground and includes a metal or an electrostatic dissipative material, and
wherein the second probe includes an electrostatic field separation surface that faces the second surface.

10. The apparatus for measuring static electricity of claim 1, wherein the second probe includes:
a second casing; and
a second electrostatic measurement structure provided in the second casing and configured to measure a static electricity of a second measurement region included in the second surface,
wherein the second casing is earthed to the ground, and
wherein the second electrostatic measurement structure is earthed to the ground separately from the second casing.

11. The apparatus for measuring static electricity of claim 10, wherein the second casing includes a second measuring hole that faces the second surface to correspond to the second measurement region.

12. The apparatus for measuring static electricity of claim 11, wherein the second casing includes:
a second casing head, which includes the second measuring hole; and
a second casing body to which the second casing head is detachably connected.

13. The apparatus for measuring static electricity of claim 11, wherein the second electrostatic measurement structure includes a second electrostatic sensor that is spaced apart from the second measuring hole in a direction opposite to a direction toward the measurement object, and faces the second measuring hole, and
wherein a length of the second electrostatic sensor in a first direction parallel to a direction in which the second measuring hole extends is equal to or greater than a length of the second measuring hole in the first direction.

14. The apparatus for measuring static electricity of claim 11, wherein the second casing includes a second sensing surface that faces the second surface and includes the second measuring hole thereon.

15. The apparatus for measuring static electricity of claim 14, wherein the second sensing surface is a curved surface that is bent from the second measuring hole in a direction opposite to a direction toward the measurement object.

16. The apparatus for measuring static electricity of claim 10, wherein the second casing includes a metal or electrostatic dissipative material.

17. The apparatus for measuring static electricity of claim 1, further comprising:
a first distance measurer spaced apart from the first surface and configured to measure a distance to the first surface; and
a second distance measurer spaced apart from the second surface and configured to measure a distance to the second surface.

18. The apparatus for measuring static electricity of claim 1, wherein the first probe includes a plurality of probes spaced apart from one another.

19. An apparatus for measuring a static electricity, comprising:
a first probe spaced apart from a first surface of a measurement object by a first distance; and
a second probe spaced apart from a second surface by a second distance, the second surface opposing the first surface in a thickness direction of the measurement object,
wherein the first probe includes:
a first casing; and
a first electrostatic measurement structure provided in the first casing to measure a static electricity of a first measurement region included in the first surface,
wherein the first distance and the second distance are smaller than a thickness of the measurement object,
wherein the first casing is earthed to a ground,
wherein the first electrostatic measurement structure is earthed to the ground separately from the first casing,
wherein the first casing includes a first measuring hole which faces the first surface and corresponds to the first measurement region,
wherein the first casing includes a metal or an electrostatic dissipative material,
wherein the second probe is earthed to the ground and includes a metal or an electrostatic dissipative material,
wherein the second probe includes an electrostatic field separation face that faces the second surface, and
wherein the electrostatic field separation face has a size equal to or larger than a size of the first measuring hole.

20. An apparatus for measuring a static electricity, comprising:
a first probe spaced apart from a first surface of a measurement object by a first distance; and
a second probe spaced apart from a second surface by a second distance, the second surface opposing the first surface in a thickness direction of the measurement object,
wherein the first probe includes:
a first casing; and
a first electrostatic measurement structure provided in the first casing and configured to measure a static electricity of a first measurement region included in the first surface,
wherein the second probe includes:
a second casing; and
a second electrostatic measurement structure provided in the second casing and configured to measure a static electricity of a second measurement region included in the second surface,
wherein the first distance and the second distance are smaller than a thickness of the measurement object,
wherein each of the first casing and the second casing are earthed to a ground,
wherein the first electrostatic measurement structure is earthed to the ground separately from the first casing,
wherein the second electrostatic measurement structure is earthed to the ground separately from the second casing,
wherein the first casing includes a first measuring hole which faces the first surface and corresponds to the first measurement region,
wherein the second casing includes a second measuring hole that faces the second surface to corresponds to the second measurement region, and
wherein each of the first casing and the second casing includes a metal or electrostatic dissipative material.
